(19) United States
(12) Patent Application Publication
(10) Pub. No.: US 2026/0181945 A1
(43) Pub. Date: Jun. 25, 2026

(54) RUGGED PLANAR MOSFET

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/393,307

(22) Filed: Nov. 18, 2025

Related U.S. Application Data
(60) Provisional application No. 63/735,953, filed on Dec. 19, 2024.

(51) Int. Cl. H10D 30/66; H10D 30/01; H10D 62/10; H10D 62/832; H10D 64/27

(52) U.S. Cl. CPC H10D 30/66; H10D 30/0291; H10D 62/109; H10D 62/8325; H10D 64/516

(57) ABSTRACT

A metal-oxide semiconductor field-effect transistor (MOSFET) including a volume of semiconductor material, a split gate, a gate oxide, and a doped material in the volume of semiconductor material. The volume of semiconductor material presents laterally spaced first and second sides and a trench spaced between the sides. The split gate presents laterally spaced apart first and second gate sections. The trench is located between the first and second gate sections. The gate oxide underlies the first and second gate sections and at least partially fills the trench. The doped material is in contact with the gate oxide.

### CROSS-REFERENCE TO RELATED APPLICATIONS

The current patent application claims the benefit under 35 U.S.C. § 119(e) of the priority date of U.S. Provisional Application Ser. No. 63/735,953; titled “RUGGED PLANAR MOSFET”; and filed Dec. 19, 2024. The Provisional Application is hereby incorporated by reference, in its entirety, into the current patent application.

### TECHNICAL FIELD

The present disclosure relates to metal oxide semiconductor field-effect transistors.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY OF THE INVENTION

In various examples of the present disclosure, a metal-oxide semiconductor field-effect transistor includes a volume of semiconductor material, a split gate, a gate oxide, and a doped material in the volume of semiconductor material. The volume of semiconductor material presents laterally spaced first and second sides and a trench spaced between the sides. The split gate presents laterally spaced apart first and second gate sections. The trench is located between the first and second gate sections. The gate oxide underlies the first and second gate sections and at least partially fills the trench. The doped material is in contact with the gate oxide.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 is a cross-sectional elevation view of an example rugged planar MOSFET; and

FIGS. 2A-2E are cross-sectional elevation views of an example rugged planar MOSFET at various stages of manufacture.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a rugged planar metal-oxide semiconductor field-effect transistor (MOSFET). The example MOSFET may be suitable for high-voltage applications, and may operate at a voltage greater than one thousand (1,000) volts (V). More specifically, the example MOSFET may be rated for a voltage of around twelve hundred (1,200) V. It will be appreciated by one of ordinary skill in the art that the example MOSFET may be suitable for lower voltage applications without departing from the scope of the present disclosure.

The example MOSFET may include a volume of semiconductor material and a split gate configuration including laterally spaced apart first and second gate sections. A trench may be provided between the gate sections. An insulating material, such as a gate oxide, may be provided in the trench (and in some cases may fill the trench). Additionally, the MOSFET may include a doped material underlying the gate sections and the trench. The doped material may have a higher doping concentration than a drift region portion of the volume of semiconductor material.

In various examples, the split gate configuration and the trench may reduce a gate-to-drain capacitance of the MOSFET. The insulating material in the trench may improve the reliability and longevity of the example MOSFET, thereby improving performance and reducing replacement costs. The doped material may reduce a resistance between the source and the drain, thereby improving reliability and performance of the example MOSFET.

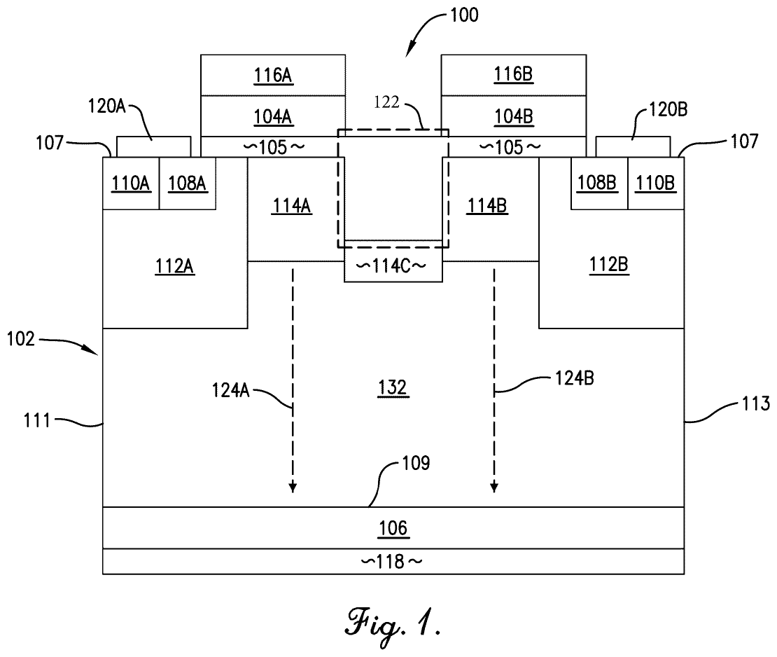

Referring to FIG. 1, an example of a MOSFET 100 is shown. The MOSFET 100 may generally include a volume of semiconductor material 102, a first gate section 104A, a second gate section 104B, a gate oxide 105, a drain 106, a first source 108A, a second source 108B, a first body contact 110A, a second body contact 110B, a first well 112A, a second well 112B, a doped material 114, a first gate contact 116A, a second gate contact 116B, a drain contact 118, a first source contact 120A, a second source contact 120B, and a trench 122.

The volume of semiconductor material 102 presents a first end 107, a second end 109 opposite and vertically spaced from the first end 107, a first side 111, and a second side 113 opposite and laterally spaced from the first side 111. The volume of semiconductor material 102 may be constructed from or include an N-type epitaxial semiconductor material. The volume of semiconductor material 102 includes a drift region 132.

The drain 106 is located at the second end 109 of the volume of semiconductor material 102 and may be constructed from or include an N+substrate material, although certain examples contemplate the drain being located elsewhere relative to the volume of semiconductor material. The volume of semiconductor material 102 may be grown or otherwise formed on the N+substrate material. The drain contact 118 may be located adjacent the drain 106 and spaced apart from the second end 109.

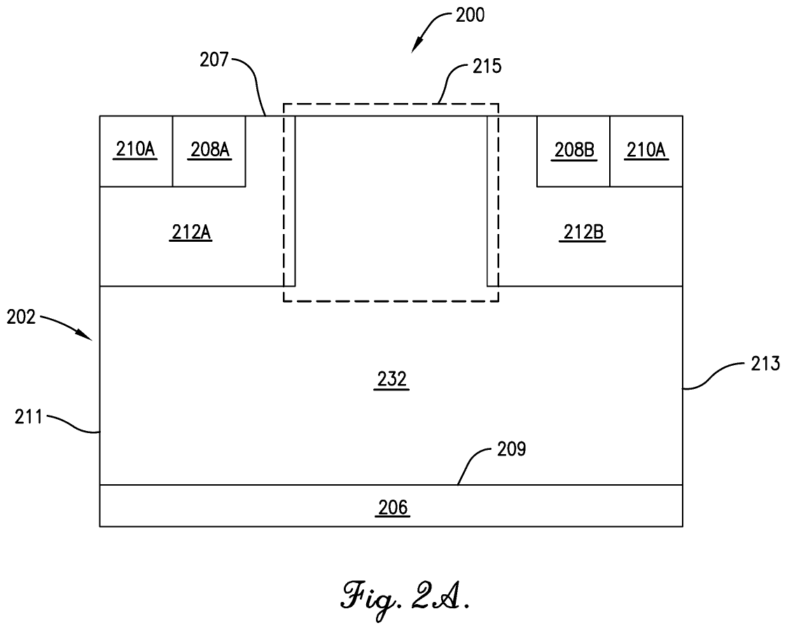

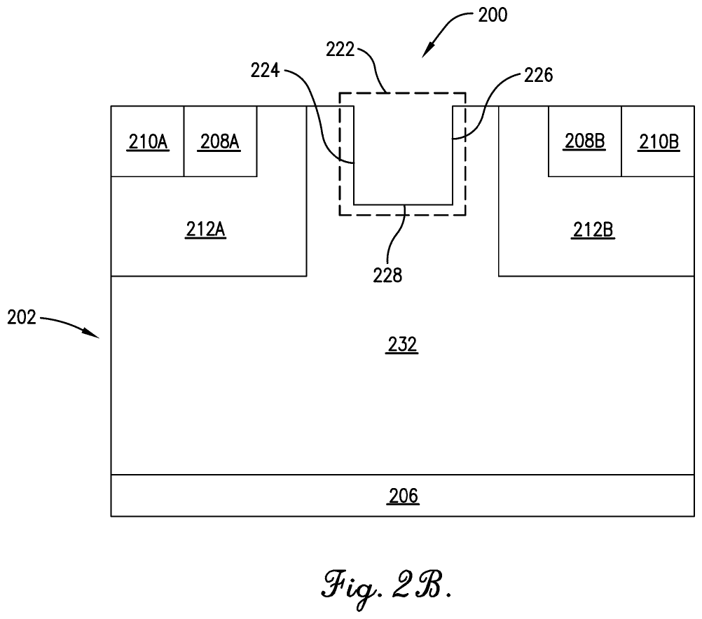

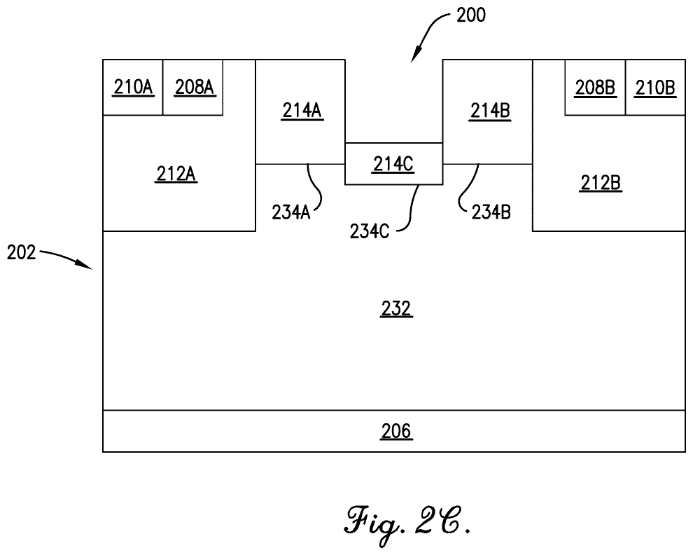

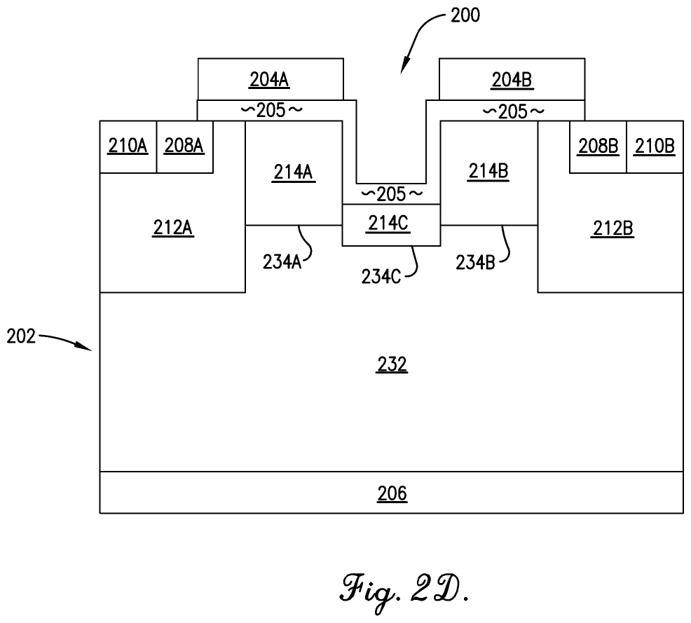

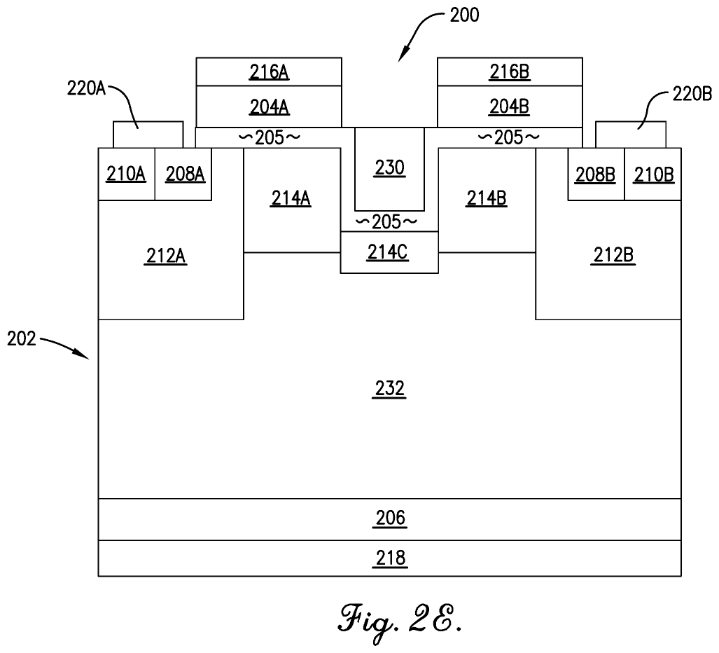

The gate oxide 105 may include first and second gate oxide portions that respectively underlie the gate sections 104A, 104B. The first and second gate oxide portions may be located above the first end 107. The gate oxide 105 additionally includes a trench oxide portion located within the trench 122. In the illustrated example, the trench oxide portion fills the trench, although it is within the ambit of other examples for the trench oxide portion to be otherwise configured, such as lining (but not filling) the trench, otherwise partially filling the trench, etc. The trench oxide portion may or may not include the same material as the first and second gate oxide portions. For instance, in certain examples, the trench oxide portion may be formed of an alternative insulator (including non-oxide insulators). The trench oxide portion is described below in more detail in connection with a trench oxide 230 of FIG. 2E. The gate oxide 105 may be constructed from or include a dielectric material, such as silicon dioxide (SiO2).

The first and second gate sections 104A, 104B may be located above the first end 107, with the gate oxide 105 interposed between the first and second gate sections 104A, 104B and the first end. The first gate section 104A is located between the trench 122 and the first side 111. The second gate section 104B is located between the trench 122 and the second side 113. The first and second gate oxide sections and the first and section gate sections 104A, 104B being located above the first end 107 may define a planar MOSFET configuration of the MOSFET 100. The first and second gate sections 104A, 104B may be formed of or include a doped polysilicon material. The doped polysilicon may be constructed from or include a P-type or N-type polysilicon material. The gate contacts 116A, 116B may be located above the respective gate sections 104A, 104B. According to some examples, the gate contacts 116A, 116B may be shorted or otherwise electrically connected.

Various structures and materials of the MOSFET 100 may be implanted (using, e.g., an ion implanter), deposited, or otherwise provided using a suitable technique in or on respective subvolumes of the volume semiconductor material 102. These structures and materials and their sizes and positions may vary and include the following. The first and second sources 108A, 108B may be constructed from or include an N+ material and may be located at the first end 107 and generally opposite the drain 106. First and second body contacts 110A, 110B may be constructed from or including a P+ material and may be located at the first end 107 and adjacent to the respective first and second sources 108A, 108B. The first body contact 110A is located adjacent the first side 111. The second body contact 110B is located adjacent the second side 113. The first source contact 120A and the second source contact 120B may be located above the first end 107, with the first source contact 120A contacting the first source 108A and the first body contact 110A and the second source contact 120B contacting the second source 108B and the second body contact 110B. According to some examples, the source contacts 120A, 120B may be shorted or otherwise electrically connected.

The first and second wells 112A, 112B may be constructed from or include a P+material and may be located below and adjacent to the respective first and second sources 40A, 40B. The first well 112A may be located adjacent the first side 111. The second well 112B is located adjacent the second side. The doped material 114 may include portions underlying respective components of the MOSFET. A first doped material portion 114A is located at the first end 107 and extends toward the second end 109 and between the well 112A and the trench 122. A second doped material portion 114B is located at the first end 107 and extends towards the second end 109 and between the well 112B and the trench 122. The first and second doped material portions 114A may underlie portions of the gate oxide 105. The first doped material portion 114A contacts the well 112A. The second doped material portion contacts the well 112B. A third doped material portion is located below the trench and extends towards the second end 109 and between the first and second doped material portions 114A, 114B.

Each of the doped material portions 114A, 114B, 114C may include distal or lowermost margins that are spaced apart from the first end 107. In various examples, the distal or lowermost margins of the doped material portions 114A, 114B may be spaced equally from the first end 107. The distal or lowermost margin of the doped material portion 114C may be spaced farther from the first end 107 than the distal or lowermost margins of the doped material portions 114A, 114B.

The doped material portion 114A may contact the doped material portion 114B, and the doped material portion 114B may contact the doped material portion 114C. Accordingly, the doped material portions 114A, 114B, 114C may extend continuously between the first and second wells 112A, 112B.

In various examples, the doped material portions 114A, 114B, 114C may underlie respective portions of the gate oxide 105. The lowermost or distal margin of each of the doped material portions 114A, 114B, 114C may be equally spaced from the respective portions of the gate oxide 105. The spacing of the lowermost or distal margins of the doped material portions 114A, 114B, 114C are described in more detail in connection with lowermost or distal margins 234A, 234B, 234C of FIGS. 2C and 2D. Alternative doped material configurations are within the ambit of some example MOSFETs. For instance, according to some examples, the doped material may be discontinuous between the wells 112A, 112B (e.g., to underlie only the trench 122). Furthermore, the portions 114A, 114B, 114C may alternatively have the same vertical thickness, present a common lowermost margin so that the entirety of the doped material is spaced evenly from the second end of the volume of semiconductor material 102, present asymmetric first and second portions, etc.

The doped material portions 114A, 114B, 114C may be formed of the same material as the drift region 132, with the doped material portions 114A, 114B, 114C having a higher doping concentration than the drift region 132. The doped material portions 114A, 114B, 114C may present a gradient doping profile, with a heavier doping concentration adjacent the gate oxide 105 relative to locations spaced apart from the gate oxide 105. For example, the doping concentration of the doped material portions 114A, 114B, 114C may be similar or greater than a doping concentration of the sources 108A, 108B near the gate oxide 105, and the doping concentrations of the doped material portions 114A, 114B, 114C may be similar or slightly greater than a doping concentration of the drift region 132 near the distal or lowermost margins of the doped material portions 114A, 114B, 114C.

First and second channels 124A, 124B may be provided by a channel portion of the volume of semiconductor material 102. The first and second channels 124A, 124B extend through the drift region 132 between the respective first and second sources 108A, 108B and the drain 106. The majority charge carriers may move and the electrical current may flow through the channels 124A, 124B. It will be understood by one of ordinary skill in the art that the dashed lines representing the channels 124A, 124B are merely representative and charge carriers moving through the channels 124A, 124B do not necessarily follow a straight line.

It will be appreciated that the example MOSFET is an N-channel MOSFET. However, certain aspects of the example MOSFET might be applicable to P-channel MOSFETs.

In operation, when a voltage, Vgs, is applied between the sources 108A, 108B and the gate sections 104A, 104B, the generated electric field creates an inversion layer at the semiconductor-dielectric interface. The inversion layer provides the channels 124A, 124B through which electrical current can flow when another voltage, Vds, is applied between the sources 108A, 108B and the drain 106. More specifically, Vgs controls the width of the depletion region at the P-N junction where the charge carriers of the P− and N− type materials diffuse into each other, which “depletes” the available concentrations of majority charge carrier in each material, and thereby controls the current, Id, from the drain 106 to the sources 110A, 110B. In the present examples, the trench 122, the gate oxide 105 filling the trench, and the doped material 114A, 114B, 114C improves reverse conduction by avoiding bipolar degradation when the parasitic P-N body diode is opened, and provides a much lower gate-to-drain capacitance (Cgd).

FIGS. 2A-2E illustrate an example rugged planar MOSFET 200 during various stages of manufacture. The MOSFET 200 may be a SiC MOSFET. Example manufacturing steps described may be utilized to form the MOSFET 100 of FIG. 1, and the components described with respect to the MOSFET 200 may be analogous to corresponding components of the MOSFET 100.

Referring to FIG. 2A, a doped material substrate 206 may be provided. The doped material substrate 206 may be constructed from or include an N+ doped substrate material.

A volume of semiconductor material 202 may be grown or otherwise deposited on the doped material substrate 206. The volume of semiconductor material 202 may present a first end 207, a second end opposite and vertically spaced from the first end 207, a first side 209, and a second side 211 opposite from and laterally spaced from the first side 209. The doped substrate material 206 may be located at the second end 209.

A region of the volume of semiconductor material 202 located between the first and second wells 212A, 212B may provide a junction field effect transistor (JFET) neck region 215. The volume of semiconductor material 202 may be constructed from or include an N-type epitaxial semiconductor material. The area of the volume of semiconductor material 202 outside of the MOSFET and generally below the JFET neck region 215 may provide a drift region 232. Channels may be formed between the sources 208A, 208B and the doped material substrate 206, such that the channels extend through the drift region 232, as shown in FIG. 1.

As shown in FIGS. 2A-2C, the volume of semiconductor material 202 may further include respective instances of various structures and materials. The respective instances of the various structures and materials may be implanted (using, e.g., an ion implanter), deposited, or otherwise provided using a suitable technique in or on respective subvolumes of the volume semiconductor material 202. These structures and materials and their sizes and positions may vary, but may generally include a first source 208A, a second source 208B, a first body contact 210A, a second body contact 210B, a first well 212A, a second well 212B, and a doped material (which in the illustrated example includes a first doped material 214A, a second doped material 214B, and a third doped material 214C).

Returning to FIG. 2A, first and second structures of P material for the respective first and second wells 212A, 212B may be implanted or otherwise provided in the respective subvolumes at the first end 207 of the volume of semiconductor material 202. First and second structures of N+ material for the respective first and second sources 108A, 108B may be implanted or otherwise provided in the respective subvolumes of the volume of semiconductor material 202 at the first end 207, over and adjacent to the respective first and second structures of P material and generally opposite the doped substrate material 206. First and second structures of P+material for the respective first and second body contacts 210A, 210B may be implanted or otherwise provided adjacent to the respective first and second sources 208A, 208B, such that each body contact 210A, 210B is located between a respective one of the sides 211, 213 and a corresponding one of the sources 208A, 208B.

Referring to FIG. 2B, a trench 222 may be formed in the volume of semiconductor material 202. The trench may be formed through an etching process or another suitable technique. In various examples, a mask may be placed across the first end 207 such that etching only occurs in an area in which the trench is formed. The mask may be removed after etching the trench.

The trench may present laterally spaced first and second trench sides 224, 226, and a trench bottom 228 extending between the trench sides 224, 226. The trench 222 may be located between the wells 212A, 212B. The trench 222 may be located between first and second gate sections 204A, 204B (as shown in FIG. 2D). The trench bottom 228 may be spaced apart from the first end 207, such that the trench extends from the first end 207 towards the second end 209. The first trench side 224 may be spaced apart from the first side 211 by a first dimension. The second trench side 226 may be spaced apart from the second side 213 by a second dimension. The first and second dimensions may be the same, although alternative (or variable) spacing is within the ambit of certain examples. The wells 212A, 212B may extend closer to the second end 209 than the trench bottom 228, although similar or alternatively arranged well-to-trench dimensions are contemplated by certain example MOSFETs.

Referring to FIG. 2C, first, second, and third instances of gradient doped N+ material for the respective first, second, and third doped material portions 214A, 214B, and 214C may be implanted or otherwise provided in the respective subvolumes of the volume of semiconductor material 202. The first and second instances of the gradient doped N+ material may be implanted or otherwise provided at the first end 207. The third instance of the gradient doped N+material may be implanted or otherwise provided at the trench bottom 228. The first doped material portion 214A may extend between the well 212A and the first trench side 224. The second doped material portion 214B may extend between the well 214 and the second trench side 226. The third doped material portion 214c may extend between the first and second doped material portions 214A, 214B, such that the first, second, and third doped material portions 214A, 214B, 214C form a continuous body of doped material extending between the first well 212A and the second well 212B. According to certain examples, the doped material may alternatively be formed of a single unitary implant which may or may not be subsequently modified (e.g., by etching or other suitable techniques).

The doped material portions 214A, 214B, 214C may present a gradient doping profile, with heavier doping concentrations near the first end 207 for the doped material portions 214A, 214B and a heavier doping concentration near the trench bottom 228 for the doped material portion 214C.

The doped material portions 214A, 214B, 214C include respective distal or lowermost margins 234A, 234B, 234C. The distal or lowermost margins 234A, 234B may be equally spaced from the first end 207. The distal or lowermost margin 234C may be spaced farther from the first end 207 than the first and second distal or lowermost margins 234A, 234B.

Referring to FIG. 2D, a layer of dielectric material 205, or gate oxide (e.g., silicon dioxide (SiO2)), may be deposited or otherwise provided over the first end 207.

First and second structures of the doped (e.g., P-type) polysilicon material may be deposited or otherwise provided over portions of the dielectric material 205 to form first and second gate sections 204A, 204B. The first and second gate sections 204A, 204B may be located on either side of the trench 222. The layer of dielectric material 205 may be etched or otherwise processed so that the dielectric material 205 is removed from the first end 207 except under and between the first and second gate sections 204A, 204B. The dielectric material 205 may line the first and second trench sides 224, 226, and the trench bottom 228. The dielectric material 205 be located above respective portions of the first and second sources 208A, 208B, and respective portions of the first and second wells 212A, 212B. The dielectric material 205 may extend above and adjacent the first and second doped material portions 214A, 214B and above the doped material portion 214C.

The dielectric material 205 may include a first oxide portion underlying the first gate section 204A, a second oxide portion underlying the second gate section 204B, and a third oxide portion at least partially filling the trench 222. The first distal margin 234A may be spaced apart from the first oxide portion by a first dimension. The second distal margin 234B may be spaced apart from the second oxide portion by a second dimension. The third distal margin 234C may be spaced apart from the third oxide portion by a third dimension. The first, second, and third dimensions may be equal. In an alternative example, the first and second dimensions may be greater than the third dimension, such that the first and second doped material portions 214A, 214B extend further from the respective oxide portions than the third doped material portion 214C. Other alternative dimensions and shapes of the doped material sections are within the ambit of certain aspects of the example MOSFET.

Referring to FIG. 2E, a second dielectric material 230 may be disposed in the trench 222. The second dielectric material 230 may include a gate oxide material and may include the same material as the dielectric layer 205 (e.g., SiO2). In an alternative example, the second dielectric material 230 may include another dielectric insulating material, such as polyphenylene sulfide. In the illustrated example, the second dielectric material 230 and the third oxide portion of the dielectric material 205 may collectively form a trench oxide portion that fills the trench 222. However, according to certain examples, the trench may be filled (or partially filled) with an alternative insulator, such that the trench contains no oxide material.

Electrical contacts 216A, 216B, 218, 220A, 220B may be added to facilitate applying appropriate electrical voltages during operation of the MOSFET 200. More specifically, first and second gate contacts 216A, 216B may be added to the respective first and second gates 204A, 204B. First and second source contacts 220A, 220B may be added to the respective first and second sources 208A, 208B. A drain contact 218 may be added that spans the substrate 206. As noted previously, according to certain examples, the gate contacts 216A, 216B may be shorted, and the source contacts 220A, 220B may be shorted.

### Feature Combinations

According to various examples of the present disclosure, a metal-oxide semiconductor field-effect transistor (MOSFET) may include a volume of semiconductor material, a split gate, a gate oxide, and a doped material in the volume of semiconductor material. The volume of semiconductor material may present laterally spaced first and second sides and a trench spaced between the sides. The split gate may present laterally spaced apart first and second gate sections. The trench may be located between the first and second gate sections. The gate oxide may underlie the first and second gate sections and at least partially fill the trench. The doped material may be in contact with the gate oxide.

The preceding example may include any one or more of the following features.

The gate oxide may fill the trench.

The volume of semiconductor material may include a drift region, the drift region and the doped material may include the same material, and the doped material may have a higher doping concentration than the drift region.

The doped material may present a gradient doping profile, with a heavier doping concentration adjacent the gate oxide relative to locations spaced from the gate oxide.

The drift region and the doped material may include N-type material.

The doped material may be implanted within the volume of semiconductor material.

The MOSFET may include laterally spaced apart first and second wells, with a portion of the first well underlying the first gate section and a portion of the second well underlying a the second gate section. The trench may be located between the wells, and the doped material may extend continuously between the first and second wells.

The doped material may include a first doped portion that extends between the first well and the trench, a second doped portion that extends between the second well and the trench, and a third doped portion that extends between the first and second doped portions and underlies the trench. Each of the doped portions may present a respective distal margin spaced furthest from the gate oxide, and the distal margins may be equally spaced from the gate oxide.

The MOSFET may include laterally spaced apart first and second wells, with a portion of the first well underling the first gate section and a portion of the second well underlying the second gate section; laterally spaced apart first and second sources adjacent the respective first and second wells, with the trench being located between the wells and the sources; a drain; and a channel provided by a channel portion of the volume of semiconductor material extending between each source and the drain.

The volume of semiconductor material may present opposite vertically spaced first and second ends. The split gate, the gate oxide, the wells, the sources, the trench, and the doped material may be located at or adjacent the first end of the volume of semiconductor material.

The drain may be located at the second end of the volume of semiconductor material.

The gate oxide may include first and second oxide portions underlying the respective first and second gate sections, and a trench oxide portion located in the trench. The first and second oxide portions and the first and second gate sections may be located above the first end of the volume of semiconductor material so as to present a planar MOSFET configuration. The trench oxide portion may fill the trench.

The doped material may extend continuously between the first and second wells.

The doped material may include a first doped portion that extends between the first well and the trench and underlies a portion of the first oxide portion, a second doped portion that extends between the second well and the trench and underlies the second oxide portion, and a third doped portion that extends between the first and second doped portions and underlies the trench oxide portion. The first doped portion may include a first distal margin spaced a first dimension from the first oxide portion, the second doped portion may include a second distal margin spaced a second dimension from the second oxide portion, and the third doped portion may include a third distal margin spaced a third dimension from the trench oxide portion. The first, second, and third dimensions may be equal.

The doped material including a first doped portion that extends between the first well and the trench and underlies a portion of the first oxide portion, a second doped portion that extends between the second well and the trench and underlies the second oxide portion, and a third doped portion that extends between the first and second doped portions and underlies the trench oxide portion. The first doped portion may include a first lowermost margin spaced from the first end of the volume of semiconductor material, the second doped portion may include a second lowermost margin spaced from the first end of the volume of semiconductor material, and the third doped portion may include a third lowermost margin spaced from the first end of the volume of semiconductor material. The third lowermost margin may be spaced further from the first end of the volume of semiconductor material than the first and second lowermost margins.

The first and second lowermost margins may be spaced equally from the first end of the volume of semiconductor material.

The first and second sources may include an N+ material, the first and second wells may include a P material, the drain may include an N+ material, the doped material may include an N+ material, and the channel portion of the volume of semiconductor material may include N material.

The MOSFET may include laterally spaced apart first and second wells, with the trench being located between the wells; and laterally spaced apart first and second sources adjacent the respective first and second wells. The gate oxide may include a first oxide portion underlying the first gate section and contacting the first well and first source, a second oxide portion underlying the second gate section and contacting the second well and the second source, a trench oxide portion located in the trench.

The doped material may extend continuously between the first and second wells.

The trench oxide portion may fill the trench.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., metal oxide semiconductor field-effect transistors), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be similarly or alternatively constructed to the illustrated MOSFET 100 or may be entirely different devices providing different operations or functions than the illustrated MOSFET 100. In other words, in practice, the illustrated device 100 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations (measured in parts per cubic centimeter) for contact implants may be approximately between 10\hat{ }18 and 10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N− doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion. In this description, references to “one embodiment”, “an embodiment”, “embodiments”,

“an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A metal oxide semiconductor field effect transistor (MOSFET), comprising:
a volume of semiconductor material presenting laterally spaced first and second sides and a trench spaced between the sides;
a split gate presenting laterally spaced apart first and second gate sections, the trench being located between the first and gate second sections;
a gate oxide underlying the first and second gate sections and at least partially filling the trench; and
a doped material in the volume of semiconductor material and in contact with the gate oxide.

2. The MOSFET of claim 1,
the volume of semiconductor material including a drift region,
the drift region and the doped material including the same material,
the doped material having a higher doping concentration than the drift region.

3. The MOSFET of claim 2, the doped material presenting a gradient doping profile, with a heavier doping concentration
adjacent the gate oxide relative to locations spaced from the gate oxide.

4. The MOSFET of claim 3, the drift region and the doped material including N-type material, the doped material being
implanted within the volume of semiconductor material.

5. The MOSFET of claim 1, comprising:
laterally spaced apart first and second wells, with a portion of the first well underlying the first gate section and a portion of the second well underlying the second gate section,
the trench being located between the wells,
the doped material extending continuously between the first and second wells.

6. The MOSFET of claim 5,
the doped material including a first doped portion that extends between the first well and the trench, a second doped portion that extends between the second well and the trench, and a third doped portion that extends between the first and second doped portions and underlies the trench,
each of the doped portions presenting a respective distal margin spaced furthest from the gate oxide,
the distal margins being equally spaced from the gate oxide.

7. The MOSFET of claim 1, comprising:
laterally spaced apart first and second wells, with a portion of the first well underling the first gate section and a portion of the second well underlying the second gate section;
laterally spaced apart first and second sources adjacent the respective first and second wells, the trench being located between the wells and the sources;
a drain; and
a channel provided by a channel portion of the volume of semiconductor material extending between each source and the drain.

8. The MOSFET of claim 7,
the volume of semiconductor material presenting opposite vertically spaced first and second ends,
the split gate, the gate oxide, the wells, the sources, the trench, and the doped material being located at or adjacent the first end of the volume of semiconductor material.

9. The MOSFET of claim 8,
the drain being located at the second end of the volume of semiconductor material.

10. The MOSFET of claim 8,
the gate oxide including first and second oxide portions underlying the respective first and second gate sections,
the gate oxide including a trench oxide portion located in the trench,
the first and second oxide portions and the first and second gate sections being located above the first end of the volume of semiconductor material so as to present a planar MOSFET configuration.

11. The MOSFET of claim 10,
the trench oxide portion filling the trench.

12. The MOSFET of claim 11,
the doped material extending continuously between the first and second wells.

13. The MOSFET of claim 12,
the doped material including a first doped portion that extends between the first well and the trench and underlies a portion of the first oxide portion, a second doped portion that extends between the second well and the trench and underlies the second oxide portion, and a third doped portion that extends between the first and second doped portions and underlies the trench oxide portion,
the first doped portion including a first distal margin spaced a first dimension from the first oxide portion,
the second doped portion including a second distal margin spaced a second dimension from the second oxide portion,
the third doped portion including a third distal margin spaced a third dimension from the trench oxide portion,
the first, second, and third dimensions being equal.

14. The MOSFET of claim 12,
the doped material including a first doped portion that extends between the first well and the trench and underlies a portion of the first oxide portion, a second doped portion that extends between the second well and the trench and underlies the second oxide portion, and a third doped portion that extends between the first and second doped portions and underlies the trench oxide portion,
the first doped portion including a first lowermost margin spaced from the first end of the volume of semiconductor material,
the second doped portion including a second lowermost margin spaced from the first end of the volume of semiconductor material,
the third doped portion including a third lowermost margin spaced from the first end of the volume of semiconductor material,
the third lowermost margin being spaced further from the first end of the volume of semiconductor material than the first and second lowermost margins.

15. The MOSFET of claim 14,
the first and second lowermost margins being spaced equally from the first end of the volume of semiconductor material.

16. The MOSFET of claim 7,
the first and second sources including an N+material,
the first and second wells including a P material,
the drain including an N+material,
the doped material including an N+material,
the channel portion of the volume of semiconductor material including N material.

17. The MOSFET of claim 1, comprising:
laterally spaced apart first and second wells, with the trench being located between the wells; and
laterally spaced apart first and second sources adjacent the respective first and second wells,
the gate oxide including a first oxide portion underlying the first gate section and contacting the first well and first source, a second oxide portion underlying the second gate section and contacting the second well and the second source, a trench oxide portion located in the trench.

18. The MOSFET of claim 17,
the doped material extending continuously between the first and second wells.

19. The MOSFET of claim 18,
the trench oxide portion filling the trench.

20. The MOSFET of claim 1,
the gate oxide filling the trench.
